(19) United States
(12) Patent Application Publication
(10) Pub. No.: US 2024/0014004 A1
(43) Pub. Date: Jan. 11, 2024

(54) DIRECT METAL NANO PATTERNING

(71) Applicant: Qatar Foundation for Education, Science and Community Development, Doha (QA)

(72) Inventors: Hicham Hamoudi, Doha (QA); Sara Iyad Mohd Saleh Ahmad, Doha (QA)

(21) Appl. No.: 18/220,369

(22) Filed: Jul. 11, 2023

Related U.S. Application Data
(60) Provisional application No. 63/388,057, filed on Jul. 11, 2022.

(51) Int. Cl. H01J 37/317; G03F 7/00

(52) U.S. Cl. CPC H01J 37/3174; G03F 7/70383; G03F 7/70558

(57) ABSTRACT

Direct metal nano patterning is provided by constructing a carbon-based sheet that include self-assembled molecular monolayers (SAMs) of metals; and applying an electron beam to the carbon-based sheet to impart a pattern of metallic nano-particles in the carbon-based sheet.

### CROSS-REFERENCES TO RELATED APPLICATIONS

The present disclosure claims the benefit of U.S. Provisional Patent Application No. 63/388,057 entitled “DIRECT METAL NANO PATTERNING” and filed on Jul. 11, 2022, which is incorporated herein by reference in its entirety.

### TECHNICAL FIELD

The present disclosure relates to a manufacturing process and the resultant goods produced thereby and more specifically to a metal patterning process using a carbon-based sheet with metal embedded therein that is irradiated to form nano-particles according to the radiation pattern applied, as a form of electron-beam lithography via Self-Assembling Nanoparticles.

### SUMMARY

The present disclosure provides new and innovative systems and methods for direct metal patterning on a carbon-based sheet built from self-assembled molecular monolayers (SAMs). The metallic atoms are embedded in the carbon-based sheet during the initial building block process of the carbon-based molecular monolayers. Upon irradiating the sheet with the electron-beam, the metallic atoms grow into metallic nanoparticles (NPs) directed to exist at certain locations on the sheet which differ based on the irradiation conditions. The present disclosure uses electron-metal interactions responsible for the NPs formation, as well as atom migration triggered by irradiation-induced electric-field responsible for the patterning of the metals on the molecular self-assembled sheet. The present disclosure provides a unique versatile new approach for patterning metallic and plasmonic nano-features directly on self-assembled carbon sheets, in addition to the fabrication of new types of structures in the areas of next-generation flexible electronics, energy conversion, rectenna technologies, sensors and detectors, among other components in electronic, optical, electromechanical devices, and the like.

In various aspects, a method, a system for performing the method, and various goods produced by the method are provided. In various aspects, the method includes:

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE DRAWINGS

FIG. 1 is a flowchart of an example method 100 for direct metal nano patterning, according to embodiments of the present disclosure.

FIG. 2 is a flowchart of an example method for synthesizing metal-containing sheets using a 3D printing, according to embodiments of the present disclosure.

FIG. 3 shows optical images taken during the formation of structures at water-hexane interface, according to embodiments of the present disclosure.

FIG. 4 shows examples of the 3D structures created using ethanol as a solvent for the C9 molecules, according to embodiments of the present disclosure.

FIG. 5 shows examples of Tunneling Electron Microscope (TEM) images of the nanosheet material created using n-hexane at different in-situ heating temperatures, according to embodiments of the present disclosure.

FIG. 6 shows example enlarged images of Silver nanoparticles on the carbon nanosheet on the TEM grid, according to embodiments of the present disclosure.

### DETAILED DESCRIPTION

The present disclosure provides systems and methods for direct metal patterning on a carbon-based sheet built from self-assembled molecular monolayers (SAMs). The method uses a novel electron-beam lithography (EBL) process of direct patterning/writing of metallic Nano Particles (NPs) using an electron-beam irradiation process on metal-self-assembled molecular-based sheets built from SAMs. In various aspects, the metallic precursor is embedded into the molecular carbon-based sheet during the fabrication process using the SAMs, which allows for the electron beam-activated formation of anisotropic metallic NPs and the simultaneous metal nano-patterning on the carbon-based sheets at the same time.

The conventional process of patterning, which has enabled the fabrication of integrated micro and nano-systems is the top-down process of EBL, which generally involves creating a pattern in a polymer film by a focused electron-beam, followed by a series of processing chemical steps to transfer the pattern onto the desired substrate. In the conventional EBL process, a polymer resist is spin-coated on top of a substrate. To create a pattern, an electron-beam is scanned on the polymer resist, followed by the resist development by chemical etching to remove the zones unaffected by the electron-beam. Then, to create the metallic pattern, the metal is deposited on the photoresist-patterned substrate. Finally, the substrate is exposed to acetone (or another solvent) to remove the photoresist and any excess metal adhered thereto. The conventional process, aside from being expensive, and time consuming to handle the multiple steps also has a limited resolution in the patterns that can be applied.

In contrast to the photoresist process, the present disclosure provides for direct patterning (also referred to as direct writing). As indicated by the name, direct patterning refers to maskless single or few-step arbitrary patterning of functional materials. Unlike polymer resist EBL, direct patterning begins with scanning an electron-beam across the surface of a film that includes of both organic and inorganic phases and sequentially writes a desired pattern, directly producing a metallic or a semiconducting material from the film. This new strategy of patterning reduces the number of processing steps and eliminates the complicated pattern transfer procedure, among other benefits.

Compared to the conventional multi-step EBL processes, the presently described direct metal patterning is substrate free, resist free, and does not require subsequent additional lift-off or metal evaporation steps to create or transform the metallic patterns. In addition, compared to other direct patterning techniques, the described process avoids developing or chemical-based steps for unexposed areas. In the present disclosure, the unexposed area constitutes the molecular-based sheet itself, which is the SAMs based nanosheet purposely patterned with the metallic nanoparticles. Stated differently, the presently described process can be defined as a one-step two-element direct EBL process, which can only use of the electron-beam and the free-standing carbon-based nanosheet to locally modify the SAMs and directly create complex surface nanostructures. The integration between the patterned metallic areas along with the unexposed carbon-sheet can be used as an electronic element such as a diode, resistor, capacitor, or transistor, depending on the electronics structure of the molecules comprising the sheet.

The disclosed method uses nano-patterning of the metallic nanoparticles, which occurs in one step directly on the molecular-based metal containing nanosheet through an electron-beam irradiation procedure. This is achieved because low-cost and morphologically stable SAMs have a strong affinity to bond with metallic atoms. This bond is a prerequisite to forming large sheets of SAMs as metal atoms act as joints connecting the molecular building blocks together. As a result, the metallic precursor for patterning is naturally embedded into the carbon-based sheet during the self-assembly of the molecular monolayers. This allows for the consequent electron-beam-activated formation of anisotropic metallic NPs and the simultaneous metal nano-patterning triggered by the irradiation-induced electric-field on the carbon-based sheets at the same time. Therefore, the free-standing metallically patterned carbon nanosheets can inherit their structural and functional elements from their parenting SAMs.

Compared to the conventional multi-step EBL processes, the present process of direct metal patterning is substrate free, resist free, and does not require subsequent additional lift-off or metal evaporation steps to create or transform the metallic patterns. In addition, compared to other direct patterning techniques, no developing or chemical-based steps of unexposed areas are required. In this process, the unexposed area constitutes the molecular-based sheet itself which is the SAMs based nanosheet purposely patterned with the metallic nanoparticles. In fact, the presently described process can be described as a one-step two-element direct EBL process considering that the process can only use the electron-beam and the freestanding carbon-based nanosheet to locally modify the SAMs and directly create complex surface nanostructures. The integration between the patterned metallic areas along with the unexposed carbon-sheet can be used as an electronic element such as diode, resistance, capacitor, or transistor, depending on the electronics structure of the molecules comprising the sheet.

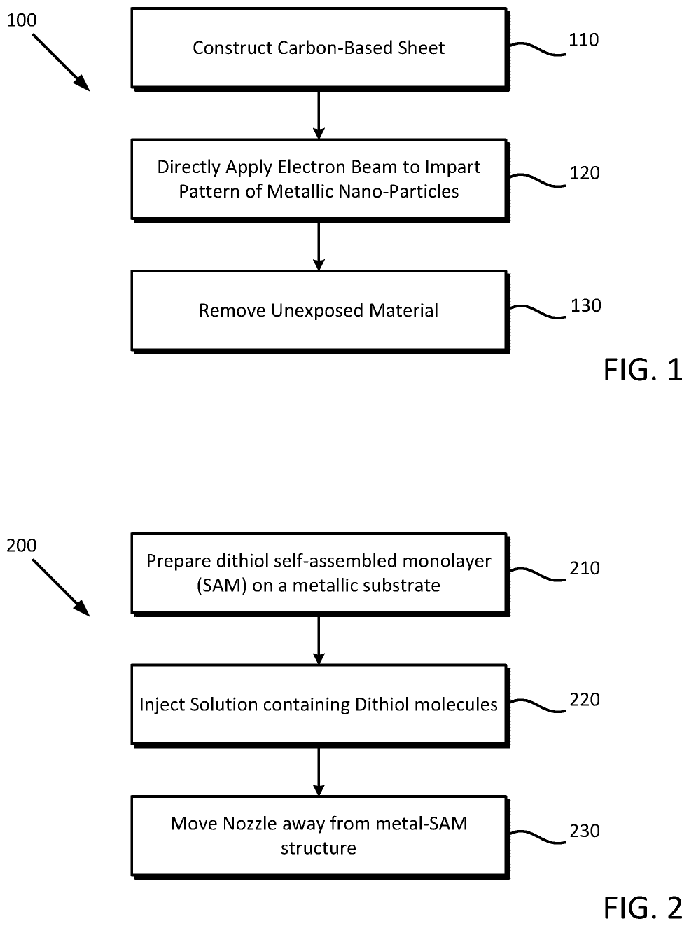

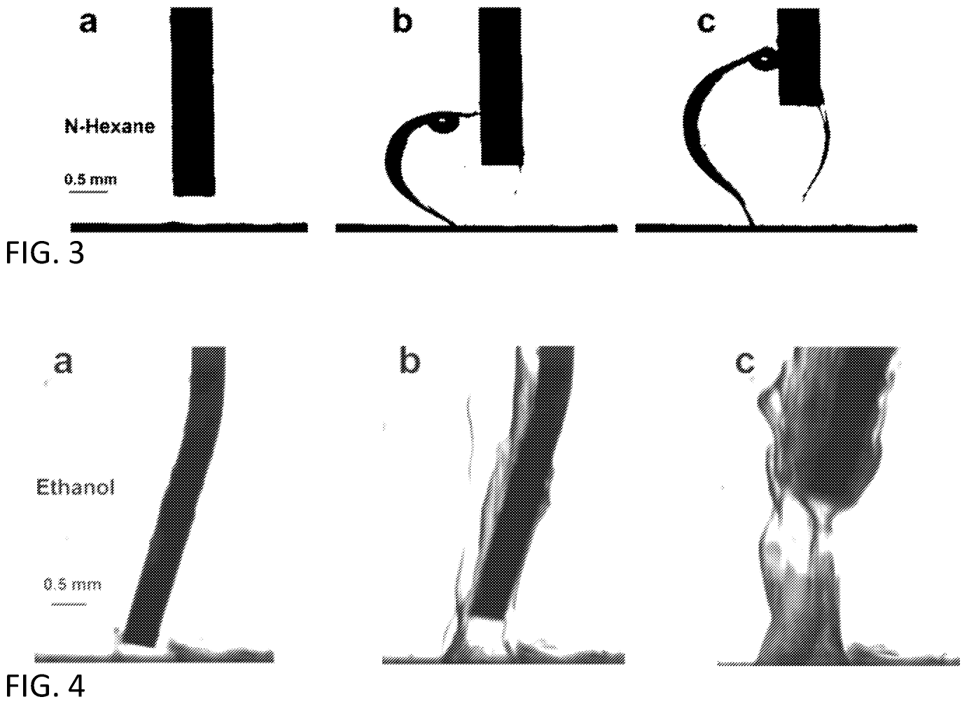

FIG. 1 is a flowchart of an example method 100 for direct metal nano patterning, according to embodiments of the present disclosure. Method 100 begins a block 110, where a carbon-based sheet is constructed. The carbon-based sheet includes metals, and is based on a SAM of dithiole molecules as both the substrate and the active material on which printing is to take place, as well as the source of the metallic element to be printed. In some aspects, the starting molecular-based metal-containing sheets are synthesized initially using a 3D printing, as described in greater detail in regard to method 200 in relation to FIG. 2.

At block 120, the carbon-based sheet is exposed to an electron beam via various protocols and patterning designs for the desired end-product. The different patterning designs can be controlled and changed depending on two main parameters during the irradiation process: the dose and diameter of the electron-beam, and the protocol of irradiation (stationary or fixed beam). The carbon-based sheet contains a polymer and metal salt that is intended for direct exposure to an electron beam, which simultaneously cross-links the polymer and reduces the metal ion to metal atoms to create the desired pattern.

In various embodiments, block 120 may be performed according to various protocols. For example, in a first protocol, a stationary electron-beam is focused on one area in the sheet, and used at a low dose. This protocol allows for the formation of the NPs and thus for the patterning to occur confined to the area irradiated by the beam.

In a second example protocol, the dose of the stationary electron-beam is increased gradually. The gradual increase of electron dose allows the NPs to form first, then allows for the manipulation of the size, density, and localization of the NPs, depending on the location and dose of the electron-beam. In each of the protocols, the electron-beam irradiation (and thus the consequent growth and patterning of the NPs) is confined and localized to the area exposed directly by the electron-beam and that the patterning of the sheet takes place towards the center of the beam in the exposed region.

In a third example protocol, a stationary beam applies a sudden exposure of a high electron dose to the sheet. The sudden high dose exposure results in the formation and thus the patterning of the NPs around the periphery of the area exposed by the electron-beam, and the positive charging of the exposed area due to the extensive and sudden secondary electron emission. This creates radial electric-field lines that forces the migration of the positive metallic ions out. In various embodiments, a “sudden” exposure, (versus a “steady” exposure) occurs for less than 10 seconds(s), 5 s, 1 s, 0.5 s, 0.1 s, 0.05 s, or any range therebetween.

In a fourth example protocol, a moving beam applies a sudden exposure of a high electron dose to the sheet. Similar to the third protocol, the sudden exposure to the high electron dose forces the metallic patterning to occur at the periphery of the exposed area, however the moving beam results in the formation of metallic patterns in parallel lines on either side of the electron beam. As a result, an empty path in the carbon-based sheet is paved with the NPs patterned at either side of the path. In each of the third and fourth protocols, crystal nucleation, formation, and growth take place on the periphery of the electron-beam and the exposed area is depleted of metal ions.

Accordingly, the electron beam may be applied in block 120 by different protocols to fabricate circuit elements of a desired pattern. Some of the protocols include where the electron beam is applied to a stationary target (e.g., the beam and substrate are both stationary) at a constant dose of electrons over the exposure period, the electron beam is applied to a stationary target at a variable dose of electrons (e.g., ramping up, ramping down) over the exposure period, the electron beam is applied to a stationary target in a sudden exposure (e.g., in a time of exposure less than the first protocol), and the electron beam is applied to a mobile target (e.g., one or both of the substrate and electron beam move relative to one another) in a sudden exposure.

These different protocols highlight the capabilities and the ease of achieving different patterning designs directly on the sheet based on the required application. For example, if these patterns are made continuous, the patterns can be used as nanoscale conductive interconnect lines, otherwise, in the shown case of metallic NPs, these sheets can be used in nano-plasmonic devices. Stated differently, carbon-based sheets with metallic inclusions are formed where the metallic atoms end up embedded in the carbon sheet. Upon electron-beam irradiation, the electron-metal interactions result in metallic NPs formation and force metallic nano-patterning through atom migration triggered by irradiation-induced electric-fields.

In various aspects, the pattern applied by the electron beam constructs a circuit element of a diode, resistor, capacitor, transistor, or the like, which may be part of a flexible circuit using the carbon-based sheet as a flexible substrate (c.f., a rigid circuit fabricated on silicon).

At block 130, an operator removes the unexposed material, leaving behind a patterned sheet of NPs. In various embodiments, the operator may use various chemical processes (e.g., etchants) to remove the areas of the sheet not irradiated (e.g., the unirradiated areas) to leave behind the patterned NPs.

Method 100 may then conclude. The described method 100 provides a versatile new approach to the nano-patterning of metals on two dimensional carbon-based sheets, which may be used for fabricating of new types of structures in the areas of next-generation flexible electronics, energy conversion, rectenna technologies, sensors and detectors, among other components in electronic, optical, electromechanical devices, and the like.

FIG. 2 is a flowchart of an example method 200 for synthesizing metal-containing sheets using a 3D printing, such as may be used in method 100 discussed in relation to FIG. 1 for direct metal nano patterning, according to embodiments of the present disclosure.

Method 200 provides for molecular self-assembly-based 3D printing method based on self-assembled monolayer (SAM) approach, which is capable of fast and continuous printing of different 3D objects with self-healing properties using molecules as building blocks and metal ions as mediators. The approach uses advances of liquid-liquid interface engineering to enable continuous formation of SAMs at the interface via intermolecular interactions. The present 3D printing approach has several advantages such as defect-free materials creation and room-temperature processing. Moreover, the resulting 3D structures show self-healing properties which are characteristic for living tissues in repairing minor damages.

Creating self-healing structures is one of the main objectives of additive manufacturing as irreversible failures limit the performance of 3D printed objects. In polymeric materials, chemical reactions such as covalent bonding, ionic and electrostatic interactions, and supramolecular assemblies, are the primary mechanisms that lead to self-healing. In the present method 200, the self-healing occurs due to the formation of dynamic metal-sulfur covalent bond formation at the liquid-liquid interface without any external trigger. This self-healing process enables one to create complex 3D structures from molecular building blocks with specific edge groups.

Method 200 begins with block 210, where a high-quality dithiol SAM on metallic substrate is prepared to avoid oxidation of the sulfurs-end groups. Dithiol molecules are the preferred building blocks for the present 3D printing approach due to the possibility of grafting metal atoms required for continuous self-assembly. The resulting SAM will be immersed into water containing metal atom precursor. Due to chemical reactions, the surface of the SAM will be grafted with the metal atoms.

At block 220, a second solution containing dithiol molecules is injected through a contact angle nozzle on top of the metal-SAM structure. Some of the molecules in this solution form the second layer of SAM due to the interaction with silver metal atoms adsorbed on top of the previous SAM and the remaining of the molecules will be expelled up together with the solution. The surface of the newly formed SAM is covered by metal atoms nearly instantaneously.

At block 230, the operator pulls the nozzle up (away from the SAM) while continuing to injection the solution containing dithiol molecules. By the injection of the dithiol molecule solution and pulling up the nozzle at the same time will, periodic and continuous metals-SAMs multilayer structures can be made by the molecular-SAM building block method.

For example, by using nonane-dithiol (C9) molecules as building blocks solvated either in n-hexane or in ethanol, method 200 can be used to create structures in water containing silver atom precursor (e.g., silver nitrate) using the setup as described. In an example embodiment, the liquids containing the molecules may be injected with flow speed of 650 μl/min and vertical nozzle speed of around 0.2 mm/s.

Pure ethanol and hexane were degassed under nitrogen gas flow for 20 min. Au (111) on Si was rinsed with absolute ethanol three times and dried under nitrogen gas flow prior to use. The 10 mM solution of C9 dithiol is prepared by dissolving the molecules in the pre-degassed hexane. The clean substrate is then immersed into the solution for SAMs formation at room temperature for C9 dithiol. The substrates are kept for 1 hour in dark condition to avoid light-induced molecular oxidation. The resulting SAMs are then sufficiently rinsed with hexane and dried under N₂ flow. The C9-dith/Au sample is then placed in the bottle filled with 100 mM of Silver Nitrate (AgNO₃) water solution, which is pre-degassed for 30 minutes to avoid oxidation. A glass syringe is used to store the well-degassed dithiol solution previously prepared and installed onto a contact angle system. The injection of the solution is accomplished by controlling the dissipation of solution flow through the contact angle nozzle.

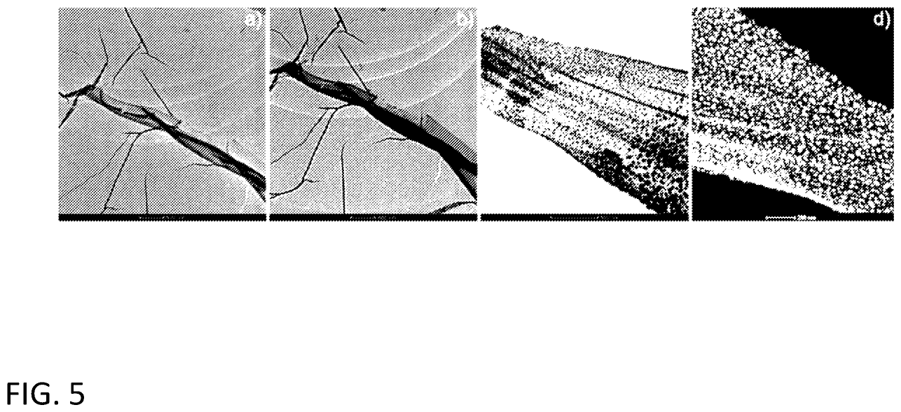

FIG. 3 shows optical images taken during the formation of structures at water-hexane interface, according to embodiments of the present disclosure. The nozzle is brought to a first distance close to the SAM-surface, and a n-hexane solution containing C9 molecules is continuously expelled, while and move the nozzle vertically up away from the deposition surface. Due to the interaction with silver atoms adsorbed on top of the first the SAM, the C9 molecules form the second monolayer. However, because of the large difference in the polarity of water and hexane, which prevents mixing of hexane with water, metal atoms cannot fully penetrate the injected hexane solution and therefore the molecules are decorated with metal atoms only at the water-hexane interface. Consequently, the described process forms 2D nanosheets with a finite thickness.

The nanosheet produced at the interface between water and n-hexane take the form of a bubble separating the two liquids. Consequently, a very thin nanosheet separating water and hexane is formed during the process. Moving the nozzle upward and simultaneously injecting the second liquid enables further growth of the nanosheet with hexane (which comes from the nozzle) confined inside the bubble. The object remains on the substrate once the nozzle is moved vertically up without injection. By fishing (e.g., removing the printed object from the substrate) the resulting nanosheet, the encapsulated hexane evaporates, and the formed nanosheet remains deposited on the substrate. The resulting 3D objects are mechanically stable during tensile tests.

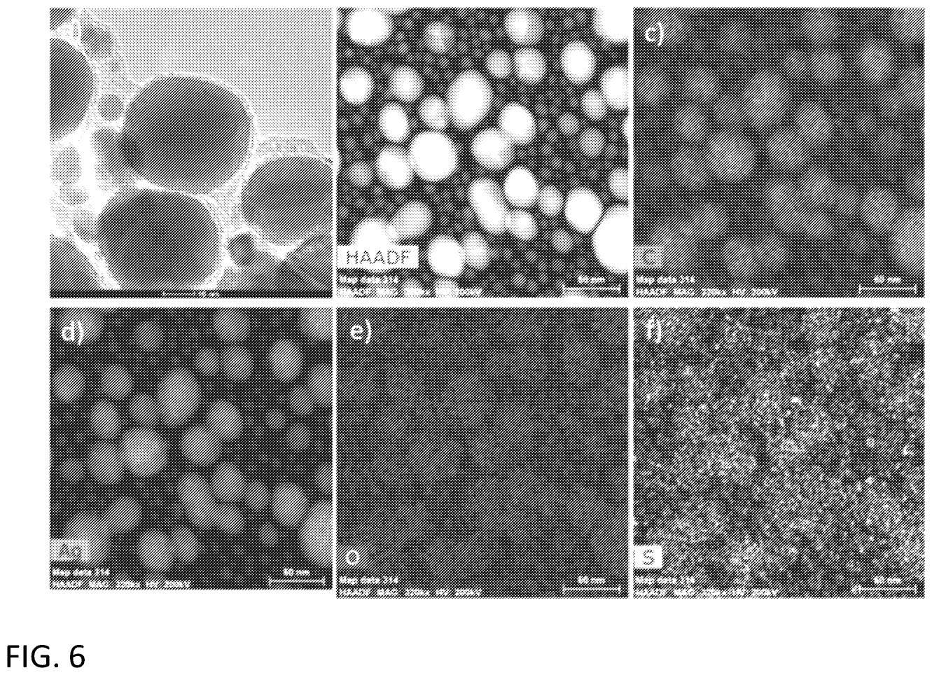

FIG. 4 shows examples of the 3D structures created using ethanol as a solvent for the C9 molecules, according to embodiments of the present disclosure. Clear structural difference is seen between the objects created in this case as compared to the samples created using n-hexane. Namely, the bubble structures are absent, but rather solid objects are obtained with the lateral size determined by the size of the nozzle (for a given location of the nozzle). The latter is due to the fact that ethanol has a similar polarity as water which allows full penetration of the metal ions to decorate the surface of the self-assembled molecules. As in the former case using hexane, the 3D object remains on the metallic surface once the nozzle is removed from the printing area. The resulting 3D object can be transferred to another substrate for further analysis.

The chemical properties of the resulting carbon materials are studied using a tunneling electron microscope (TEM) at different imaging modes (HR-TEM as well as STEM). Electron beams can induce significant structural changes and radiation damage to carbon materials, which would prevent obtaining the desired information in imaging and chemical analysis in the TEM. However, the formed carbon structures in this study show significant resistance to the electron beam indicating good stability of the samples. The estimated thickness of the nanosheet structure created using n-hexane was ˜5 nm. The estimated thickness of the structures created using ethanol varies between 250 nm up to 4 μm as revealed in profilometer measurements.

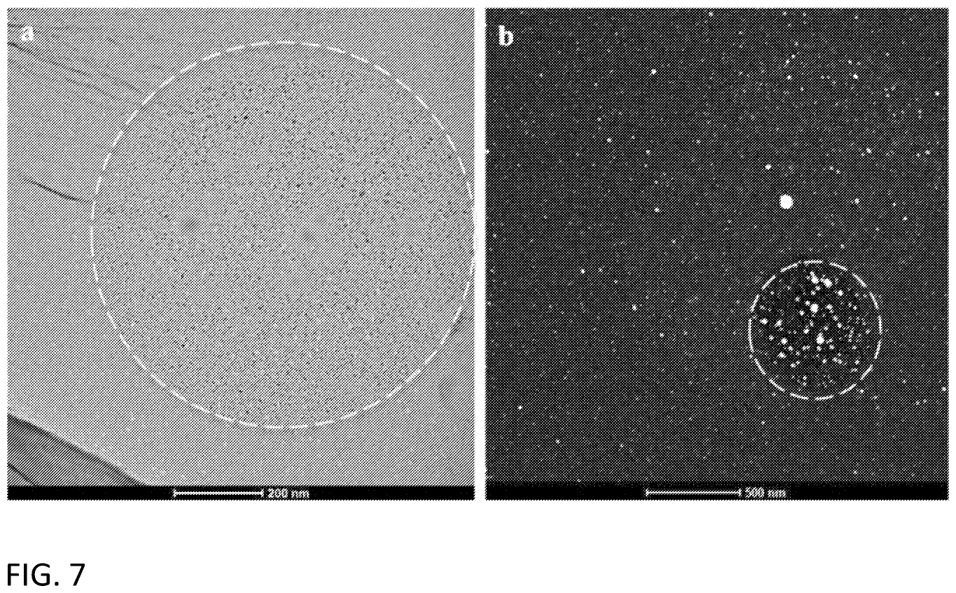

FIG. 5 shows examples of TEM images of the nanosheet material created using n-hexane at different in-situ heating temperatures, according to embodiments of the present disclosure. The annealing treatment at temperatures up to 400° C. results in the formation of Silver (Ag) nanoparticles throughout the carbon-host matrix, with a temperature-dependent size distribution. The growth of Ag nanoparticles was studied by in-situ annealing processes using electron diffraction. The diffraction study showed that the temperature-trigger of the formation of the nanoparticles is between 100 and 200° C., the analysis of hundreds of particles in the film showed an average diameter of 3.03 nm at 200° C. Subsequent annealing at 550° C. produces aggregation of particles forming a larger Ag-nanoparticle, with particle size of more than 60 nm, which can be attributed to the recrystallization and grain growth process.

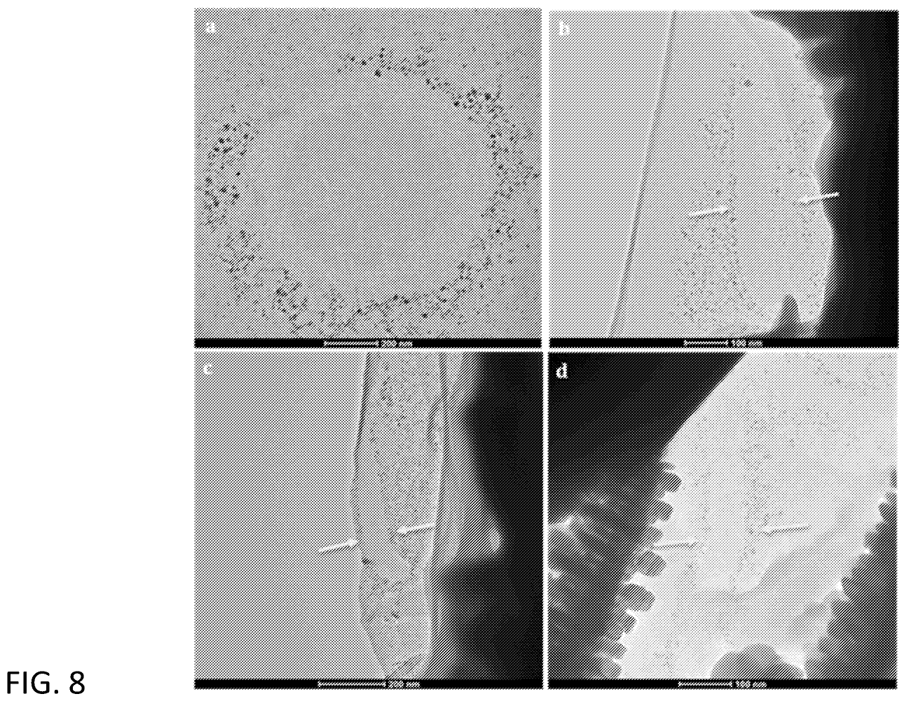

FIG. 6 shows example enlarged images of Ag nanoparticles on the carbon nanosheet on the TEM grid, according to embodiments of the present disclosure. Ag nanoparticles of different sizes are created during the annealing process. Experimentally, it has been seen that Ag nanoparticles are decorated homogenously by C and S atoms, and that the average size of the nanoparticles and their distribution in the carbon-matrix changes according to different annealing temperatures.

Another important feature that affects the particles size is the chemical nature of the surrounding matrix. The rate of diffusion of some metals such as Ag throughout a self-assembly building block 3D depends significantly on the Ag—S binding energies. Therefore, the host matrix is expected to have an important role on the nucleation and growth mechanisms of the Ag nanoparticles. This matrix plays an important role on stabilizing the nanoparticle growth by imposing a pressure on the particle surface.

To test the self-healing properties of the 3D-printed objects, two separately printed structures are placed in contact. Both structures are created using n-hexane as a solvent for the molecules, and have tubular structures. It is seen that the fusion between the two structures does not occur because the molecular sulfur-end group of both structures are saturated by silver ions, resulting in electrostatic repulsion between the objects. However, when additional molecules are injected through a hexane solution to decorate the surface of the top object with unsaturated molecule, merging occurs instantly, and the objects are self-repaired. This adhesion process is attributed to the formation of silver-sulfur bonds. Additional experiments show that self-healing can be obtained in freshly printed specimens as well as in prior-printed objects with the same efficiency and speed.

As used herein, various chemical compounds are referred to by associated element abbreviations set by the International Union of Pure and Applied Chemistry (IUPAC), which one of ordinary skill in the relevant art will be familiar with. Similarly, various units of measure may be used herein, which are referred to by associated short forms as set by the International System of Units (SI), which one of ordinary skill in the relevant art will be familiar with.

Certain terms are used throughout the description and claims to refer to particular features or components. As one skilled in the art will appreciate, different persons may refer to the same feature or component by different names. This document does not intend to distinguish between components or features that differ in name but not function.

As used herein, “about,” “approximately” and “substantially” are understood to refer to numbers in a range of the referenced number, for example the range of −10% to +10% of the referenced number, preferably −5% to +5% of the referenced number, more preferably −1% to +1% of the referenced number, most preferably −0.1% to +0.1% of the referenced number.

Furthermore, all numerical ranges herein should be understood to include all integers, whole numbers, or fractions, within the range. Moreover, these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth.

As used in the present disclosure, a phrase referring to “at least one of” a list of items refers to any set of those items, including sets with a single member, and every potential combination thereof. For example, when referencing “at least one of A, B, or C” or “at least one of A, B, and C”, the phrase is intended to cover the sets of: A, B, C, A-B, B-C, and A-B-C, where the sets may include one or multiple instances of a given member (e.g., A-A, A-A-A, A-A-B, A-A-B-B-C-C-C, etc.) and any ordering thereof. For avoidance of doubt, the phrase “at least one of A, B, and C” shall not be interpreted to mean “at least one of A, at least one of B, and at least one of C”.

Although the present invention has been described in certain specific aspects, many additional modifications and variations would be apparent to those skilled in the art. In particular, any of the various processes described above can be performed in alternative sequences and/or in parallel (on the same or on different computing devices) in order to achieve similar results in a manner that is more appropriate to the requirements of a specific application. It is therefore to be understood that the present invention can be practiced otherwise than specifically described without departing from the scope and spirit of the present invention. Thus, embodiments of the present invention should be considered in all respects as illustrative and not restrictive. It will be evident to the annotator skilled in the art to freely combine several or all of the embodiments discussed here as deemed suitable for a specific application of the invention. Throughout this disclosure, terms like “advantageous”, “exemplary” or “preferred” indicate elements or dimensions which are particularly suitable (but not essential) to the invention or an embodiment thereof, and may be modified wherever deemed suitable by the skilled annotator, except where expressly required. Accordingly, the scope of the invention should be determined not by the embodiments illustrated, but by the appended claims and their equivalents.

1-15. (canceled)

16. A method for direct metal patterning on a carbon-based sheet built from self-assembled molecular monolayers (SAMs), comprising:
embedding metallic atoms in the carbon-based sheet during a building block process of carbon-based molecular monolayers in the carbon-based sheet;
irradiating the carbon-based sheet with an electron beam or photons beam including Ultraviolet (UV) radiation to induce growth of metallic nanoparticles (NPs) at specific locations on the carbon-based sheet based on irradiation conditions; and
utilizing electron-metal or photon metal interactions and irradiation-induced electric-field to achieve both NP formation and metal nanopatterning on the carbon-based sheet.

17. The method of claim 16, wherein the metallic NPs exhibit anisotropic growth and are directed to exist at predetermined locations on the carbon-based sheet.

18. A substrate-free, resist-free method for direct metal patterning, comprising:
using a metal-containing carbon-based sheet constructed from self-assembled monolayers of dithiole molecules or molecules with different end-functional groups as both the substrate and active material for patterning;
performing electron-beam irradiation or ultraviolet (UV) radiation on the metal-containing carbon-based sheet to induce formation of metallic nanoparticles and simultaneous metal nano-patterning; and
eliminating need for additional lift-off or metal evaporation steps typically associated with traditional patterning processes.

19. The method of claim 18, wherein unexposed portions of the metal-containing carbon-based sheet, together with patterned metallic areas, form an integrated electronic component such as a diode, resistance, capacitor, or transistor, based on an electronic structure of molecules comprising the metal-containing carbon-based sheet.

20. A direct electron-beam lithography method for single-step metallic patterning on self-assembled molecular-based sheets, comprising:
using electron-beam irradiation or ultraviolet (UV) radiation on a metal-containing carbon-based sheet to create metallic nanoparticles through electron or photon-metal interactions and atom migration induced by irradiation-induced electric-fields; and
achieving different patterning designs by controlling parameters including electron-beam dose, diameter, and an irradiation method having a stationary or moving beam.

21. The method of claim 20, wherein metallic patterning occurs on a periphery of an exposed area when subjected to a sudden high electron dose, resulting in formation of metallic patterns in parallel lines when using a moving electron beam.

22. A carbon-based sheet patterned with metallic nanoparticles, produced by a one-step two-element direct electron-beam or photo-lithography process, comprising:
using an electron beam or photon-beam and a metal-containing carbon-based sheet constructed from self-assembled monolayers (SAMs) to locally modify the SAMs and create complex surface nanostructures; and
incorporating patterned metallic areas and unexposed carbon-sheet as electronic components, including one or more of nanoscale conductive interconnect lines, diodes, resistors, capacitors, or transistors, depending on an electronics structure of molecules comprising the metal-containing carbon-based sheet.
